(19) United States
(12) Patent Application Publication
(10) Pub. No.: US 2012/0273348 A1
(43) Pub. Date: Nov. 1, 2012

(54) Indium Target And Manufacturing Method Thereof

(75) Inventors: Yousuke Endo, Kitaibaraki-shi (JP); Masaru Sakamoto, Kitaibaraki-shi (JP)

(73) Assignee: JX NIPPON MINING & METALS CORPORATION, Chiyoda-ku, Tokyo (JP)

(21) Appl. No.: 13/504,338

(22) PCT Filed: Jul. 7, 2011
(86) PCT No.: PCT/JP2011/065587

§ 371 Date: Apr. 26, 2012

(30) Foreign Application Priority Data
Apr. 19, 2011 (JP) 2011-093071

(51) Int. Cl. C23C 14/34; B22D 25/00

(52) U.S. Cl. 204/298.13; 164/47

(57) ABSTRACT

The present invention provides a novel indium target and manufacturing method thereof, where an abnormal electrical discharge at sputtering and a generation of particles in a produced film can be inhibited excellently. The indium target contains not more than 1500 number/gram of inclusions having a particle size of 0.5 μm to 20 μm.

### TECHNICAL FIELD OF THE INVENTION

The present invention relates to an indium target and manufacturing method thereof.

### BACKGROUND OF THE INVENTION

Traditionally, indium target is produced in a manner such that indium is poured into a mold after indium alloy and the like are attached on a backing plate, and then the indium is cast. In such melting and casting method for indium target, raw indium supplied in the mold can form oxides by reacting with oxygen in the air. However, existence of such insulating oxides in the indium target causes problems of generation of abnormal electrical discharge at forming a thin film by sputtering, generation of particles into the formed thin film, and the like.

With respect to such problems, in Patent document 1, predetermined amount of raw indium is poured into a mold in multiple supplies instead of supply at one time. Each time indium oxide is produced on a surface of molten indium, the indium oxide is removed. Next, an indium target is produced by grinding a surface of the ingot produced by cooling. Patent document 1 discloses that generation of oxides in the produced indium target can be inhibited by the method.

(Patent document 1) Japanese Patent Application laid-Open Publication No. 2010-24474

### SUMMARY OF THE INVENTION

As described above, traditionally, emphasis is put on controlling concentration of oxygen in the indium target as means of inhibiting an abnormal electrical discharge at sputtering and a generation of particles in a produced film. In this way, traditionally, a small amount of inclusion existing in the indium target has not been regarded as a problem, and therefore, studies for removing or reducing these inclusions have not been conducted.

The present invention aims to provide a novel indium target and manufacturing method thereof, where an abnormal electrical discharge at sputtering and a generation of particles in a produced film can be inhibited excellently.

The inventors have diligently studied to cope with the requirements, and eventually have found out, the generation of the abnormal electrical discharge at sputtering results from foreign substances having a predetermined particle size in the indium target, and the abnormal electrical discharge at sputtering and the generation of particles in a produced film can be inhibited excellently by controlling a contained amount of the foreign substances having the predetermined particle size.

The present invention, produced on the basis of the above findings, in one aspect, is an indium target containing not more than 1500 number/gram of inclusions having a particle size of 0.5 μm to 20 μm.

The present invention is, in one embodiment, the indium target containing not more than 500 number/gram of inclusions having a particle size of 0.5 μm to 20 μm.

The present invention is, in another embodiment, the indium target, wherein the inclusion is one or more selected from metal, metal oxide, carbon, carbon compound and chloride compound.

The present invention is, in yet another embodiment, the indium target, wherein the inclusion is one or more metals selected from Fe, Cr, Ni, Si, Al and Co, or oxide of the metal.

The present invention, in another aspect, is a manufacturing method of an indium comprising melting raw indium in a container, supplying the melted indium to a mold through a plumbing, and then casting the indium by cooling in the mold,
wherein surface roughness (Ra) of parts in contact with the raw indium, of the container, the plumbing and the mold, is not more than 5 μm.

### Advantageous Effect of the Invention

The present invention can provide a novel indium target and manufacturing method thereof, where an abnormal electrical discharge at sputtering and a generation of particles in a produced film can be inhibited excellently.

### BRIEF DESCRIPTION OF THE FIGURES

FIG. 1A indicates a SEM picture provided by SEM/EDX analysis of #1 of working example 1.

FIG. 1B indicates an element distribution chart provided by SEM/EDX analysis of #1 of working example 1.

FIG. 2A indicates a SEM picture provided by SEM/EDX analysis of #2 of working example 1.

FIG. 2B indicates an element distribution chart provided by SEM/EDX analysis of #2 of working example 1.

FIG. 3A indicates a SEM picture provided by SEM/EDX analysis of #3 of working example 1.

FIG. 3B indicates an element distribution chart provided by SEM/EDX analysis of #3 of working example 1.

FIG. 4A indicates a SEM picture provided by SEM/EDX analysis of #4 of working example 1.

FIG. 4B indicates an element distribution chart provided by SEM/EDX analysis of #4 of working example 1.

FIG. 5A indicates a SEM picture provided by SEM/EDX analysis of #5 of working example 1.

FIG. 5B indicates an element distribution chart provided by SEM/EDX analysis of #5 of working example 1.

FIG. 6A indicates a SEM picture provided by SEM/EDX analysis of #6 of working example 1.

FIG. 6B indicates an element distribution chart provided by SEM/EDX analysis of #6 of working example 1.

FIG. 7A indicates a SEM picture provided by SEM/EDX analysis of #7 of working example 1.

FIG. 7B indicates an element distribution chart provided by SEM/EDX analysis of #7 of working example 1.

FIG. 8A indicates a SEM picture provided by SEM/EDX analysis of #8 of working example 1.

FIG. 8B indicates an element distribution chart provided by SEM/EDX analysis of #8 of working example 1.

FIG. 9A indicates a SEM picture provided by SEM/EDX analysis of #9 of working example 1.

FIG. 9B indicates an element distribution chart provided by SEM/EDX analysis of #9 of working example 1.

FIG. 10A indicates a SEM picture provided by SEM/EDX analysis of #10 of working example 1.

FIG. 10B indicates an element distribution chart provided by SEM/EDX analysis of #10 of working example 1.

FIG. 11A indicates a SEM picture provided by SEM/EDX analysis of membrane filter of working example 1.

FIG. 11B indicates an element distribution chart provided by SEM/EDX analysis of membrane filter of working example 1.

### DESCRIPTION OF THE PREFERRED EMBODIMENTS

The indium target of the present invention contains not more than 1500 number/gram of inclusions having a particle size of 0.5 μm to 20 μm. The inclusion results from impurities contained in raw indium, and impurities or products mixed mainly in manufacturing process. The inclusion means a solid body existing in structures of the indium target. The inclusion is, for example, one or more selected from metal, metal oxide, carbon, carbon compound and chloride compound. The inclusion may be one or more metals selected from Fe, Cr, Ni, Si, Al and Co, or oxide of the metal.

The inclusion in the indium target causes problems of an abnormal electrical discharge at sputtering and a generation of particles in a produced film. However, in the indium target of the present invention, the particle size and the number density of the inclusion are controlled as described above. Accordingly, those problems can be inhibited excellently. The particle size of the inclusion is limited to not more than 20 μm. Because there is little possibility that the inclusion having a particular size of over 20 μm is mixed in. Further, because the amount of the inclusion is correlated to the amount of the inclusion having a particular size of not more than 20 μm and therefore it is only necessary to consider a density of the inclusion having a particular size of not more than 20 μm, even if the inclusion having a particular size of over 20 μm is mixed in. The particle size of the inclusion is limited to not less than 0.5 μm. Because the inclusions having a particular size of not more than 0.5 μm are very small and therefore have little influence on the abnormal electrical discharge. Further, the abnormal electrical discharge can be inhibited because the number density of the inclusion is not more than 1500 number/gram.

The smaller the particular size of the inclusion is, the better. The number density of the inclusion is preferably not more than 500 number/gram, and more preferably not more than 300 number/gram.

The particular size of the inclusion can be obtained by measuring with “light scattering automatic particle counter for liquid” (manufactured by Kyushu RION). In the measuring method, the particle size is sorted out in the liquid and the concentration and the number of the particle are measured, and it is also called “liquid-borne particle counter” and based on JIS B 9925 (hereafter, the measurement is also referred to as “liquid-borne particle counter”).

To explain the measuring method particularly, 5 g of the sample is dissolved with 200 ml of acid in a slow manner lest the inclusion be dissolved, and then it is diluted to 500 ml with pure water. Next, 10 ml of the diluted solution is measured by the liquid-borne particle counter. For example, when the number of the inclusion is 800 number/ml, the number density of the inclusion is 8000 number/gram because 0.1 g of the sample is measured in 10 ml.

In the present invention, the number of the inclusion may be measured by not only the liquid-borne particle counter but other means, if the other means can measure the number of the inclusion likewise.

The indium target of the present invention can be suitably used as various sputtering targets such as a sputtering target for forming photoabsorption layer of CIGS system thin-film solar cell.

An appropriate example of a manufacturing method, of the indium target of the present invention, will be explained step by step. At first, raw indium is melted in a predetermined container. The raw indium to be used, preferably has high purity, because conversion efficiency of solar cell, formed with the raw material, deteriorates when impurities are contained in the raw indium. For example, indium of 99.99 mass % (purity 4N) or more in purity can be used for the raw material. Next, the melted raw indium is supplied into a mold through a plumbing.

The inclusion in the indium target is profoundly affected by purity of raw material as well as surface roughness (Ra) of parts in contact with the raw indium in the manufacturing process of the target. Accordingly, the container, the plumbing and the mold used in the present invention, have a surface roughness (Ra) of parts in contact with the raw indium, of not more than 5 μm. Constitutional material of the container, the plumbing and the mold are not limited in particular, but exemplified materials can be represented by stainless steel and the like, which don't contaminate the raw indium. The value “not more than 5 μm” of surface roughness (Ra) of parts in contact with the raw indium, of the container, the plumbing and the mold in the present invention, is exceedingly small compared to those which are commonly used in this technical field. Such a surface in contact can be provided by an electrolytic grinding process and the like. The surface roughness (Ra) of parts in contact with the raw indium, of the container, the plumbing and the mold, is preferably not more than 3 μm, more preferably not more than 1 μm.

As described above, the manufacturing method of the indium target of the present invention focuses on the surface roughness (Ra) of parts in contact with the raw indium, especially the surface roughness (Ra) of the parts of the container, the plumbing and the mold, during the process of manufacturing the target. Accordingly, while the surface of the container, the plumbing and the mold, becomes rough by their continuous use in traditional manufacturing methods and it also causes a problem that the surface roughness (Ra) increases, the present invention always pay attention to these and keeps the surface roughness (Ra) of the parts not more than 5 μm. Therefore, the present invention can continue to prevent the indium target from including the inclusion having a particle size of 0.5 μm to 20 μm.

Thereafter, the indium ingot is formed by cooled to room temperature. Cooling rate may be obtained by natural cooling by air. Next, if necessary, cold rolling is conducted for the produced ingot to an intended thickness, and further if necessary, acid wash, degreasing and cutting operations for surface are conducted, and then the indium target is produced.

The surface roughness (Ra) of the parts in contact with the raw indium, of the container in which the raw indium was melted, the plumbing through which the indium was supplied to the mold, and the mold, can be not more than 5 μm by the manufacturing method of the present invention. Accordingly, there is little possibility that metals such as iron, chrome and nickel and oxides thereof, included in stainless steel, which is a constitutional material of interior portions of the container, the plumbing and the mold, are contained in the indium while the indium flows. Therefore, the produced indium target contains not more than 1500 number/gram of inclusions having a particle size of 0.5 μm to 20 μm.

### EXAMPLES

Examples of the present invention, with comparative examples, will be described as follows, but the following examples are provided for better understanding of the present invention and its advantages, and intended to be non-limiting.

### Working Example 1

At first, raw indium of purity 4N was melted at 160° C. in a container and then the molten indium was poured into a column-shaped mold of 205 mm in diameter and 7 mm in height, through a plumbing. Next, an indium ingot was produced by coagulating with natural cooling, and then the indium ingot was processed to discoid shape of 204 mm in diameter and 6 mm in thickness, and thereby a sputtering target was produced. With regard to the container in which the raw indium was melted, the plumbing through which the indium was supplied to the mold, and the mold, used in this example, were made of steel materials and have the surface roughness (Ra) of parts in contact with the raw indium, of 3 μm.

### Working Examples 2 and 3

Indium targets were produced in a manner similar to the working example 1, except that the surface roughness (Ra) of parts in contact with the raw indium, of the container in which the raw indium was melted, the plumbing through which the indium was supplied to the mold, and the mold, was 1 μm (working example 2) and 5 μm (working example 3).

### Comparative Examples 1 and 2

Indium targets were produced in a manner similar to the working example 1, except that the surface roughness (Ra) of parts in contact with the raw indium, of the container in which the raw indium was melted, the plumbing through which the indium was supplied to the mold, and the mold, was 22 μm (comparative example 1) and 10 μm (comparative example 2).

### (Measurement of Inclusion and Abnormal Electrical Discharge)

5.0 g of the sample was taken from each of the indium target produced in working examples and comparative examples, and then dissolved with 200 ml of undiluted hydrochloric acid in a slow manner lest the inclusion be dissolved, and next, it was diluted to 500 ml with extra-pure water. Next, 10 ml of the diluted solution was taken and then the number of the inclusion in the liquid was measured by light scattering automatic particle counter for liquid manufactured by Kyushu RION (liquid-borne particle counter). This measurement was repeated three times and the averaged value was calculated.

Further, the indium targets of working examples and comparative examples were sputtered for 30 minutes by SPF-313H sputtering equipment manufactured by ANELVA with the conditions that ultimate vacuum pressure in a chamber before the start of sputtering was 1×10⁻⁴ Pa, pressure at sputtering was 0.5 Pa, flow volume of argon sputtering gas was 5 SCCM, sputtering power was 650W, and then the number of abnormal electrical discharge, obtained by visual observation, during the sputtering, was measured.

The measurement results are shown in Table 1.

TABLE 1

| | | Inclusion | | | | |
|---|---|---|---|---|---|---|
| | | in each particular size | | | | Number |
| | Surface | (number/gram) | | | Total | of |
| | rough- | 0.5 μm | 2.0 μm | 10 μm | (num- | abnormal |
| | ness | to | to | to | ber/ | electrical |
| | (μm) | 2.0 μm | 10 μm | 20 μm | gram) | discharge |
| Working | 3 | 1014 | 53 | 1 | 1068 | 0 |
| example 1 | | | | | | |
| Working | 1 | 250 | 10 | 0 | 260 | 0 |
| example 2 | | | | | | |
| Working | 5 | 1342 | 70 | 1 | 1413 | 0 |
| example 3 | | | | | | |
| Comparative | 22 | 7056 | 1873 | 7 | 8936 | 56 |
| example 1 | | | | | | |
| Comparative | 10 | 4156 | 856 | 3 | 5015 | 15 |
| example 2 | | | | | | |

### (Analysis of Particles)

With regard to working example 1 and comparative example 1, the diluted solution, prepared in the measurement of the inclusion, was filtered by PTFE (polytetrafluoroethylene) membrane filter having a pore size of 0.2 μm. Next, 10 particles (#1 to #10) were randomly selected from the observed particles and then SEM/EDX (scanning analytical electron microscope) analysis was conducted on them with the membrane filter itself.

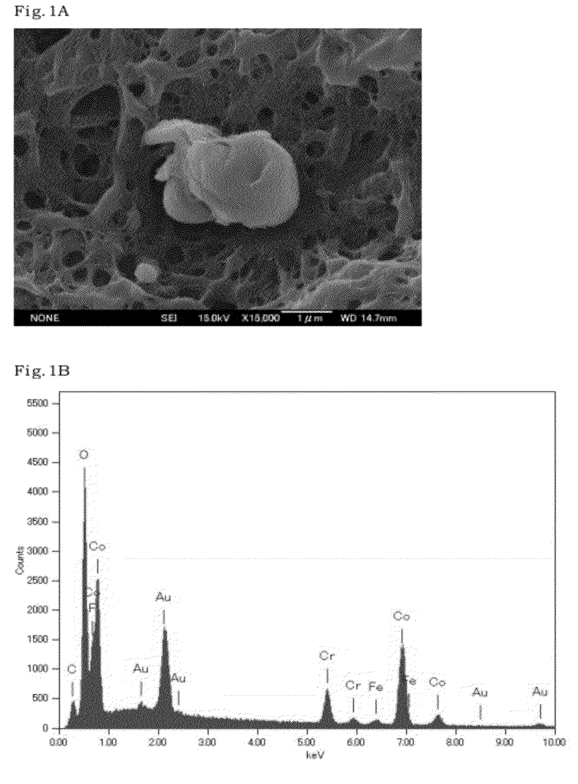

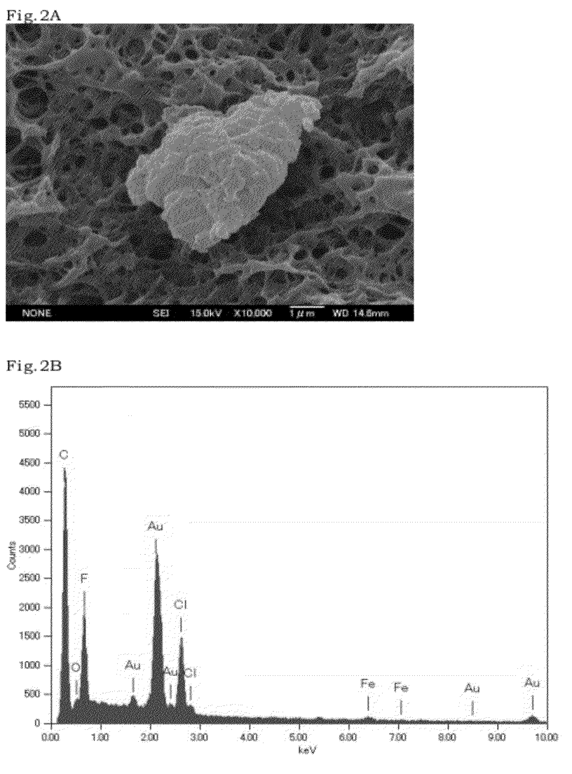

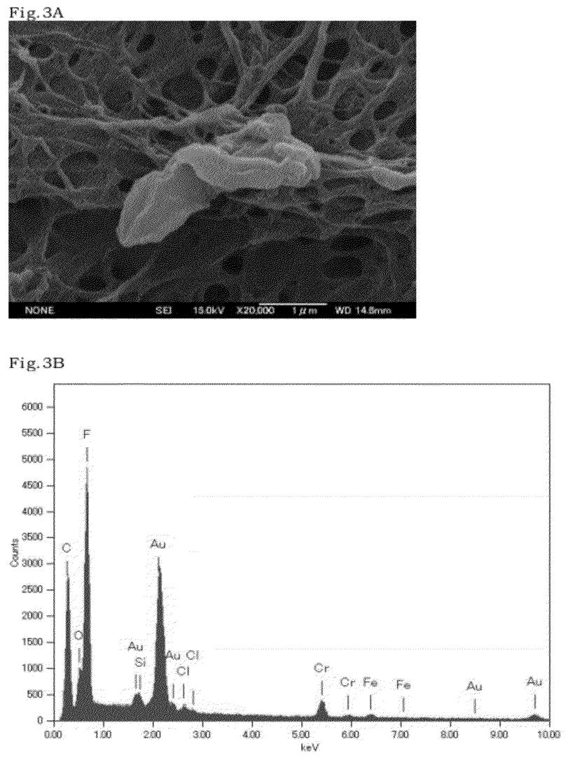

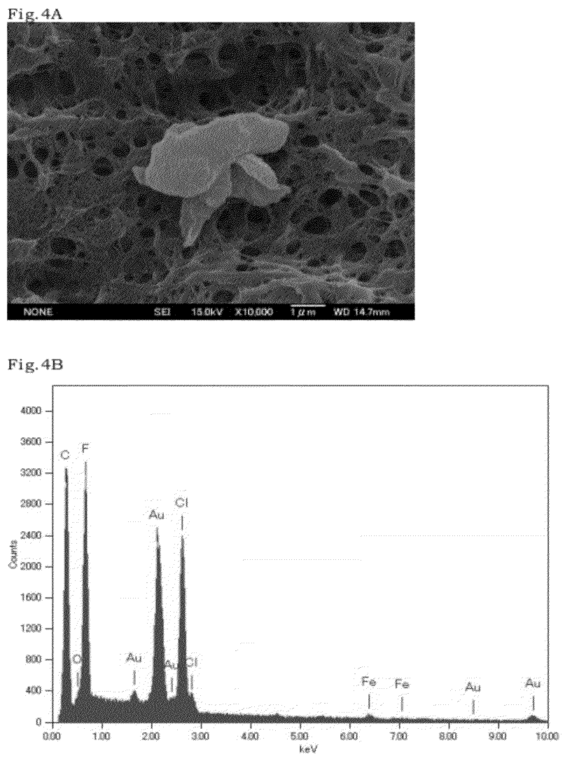

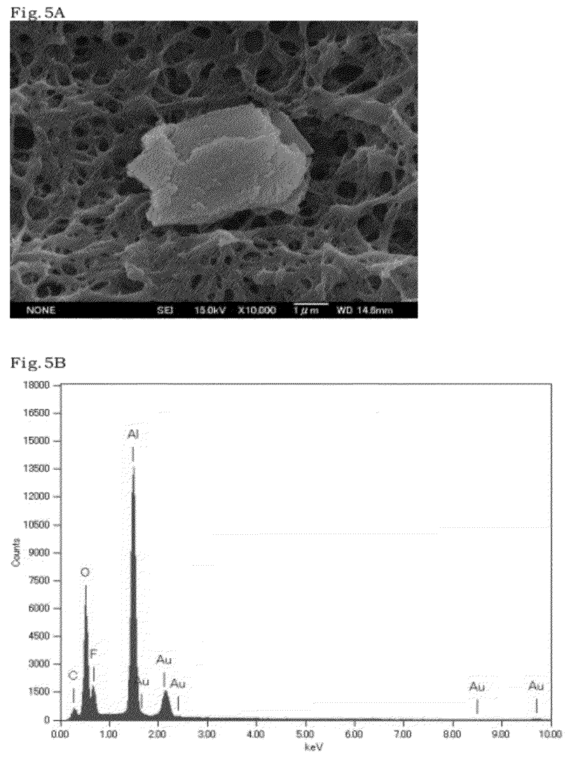

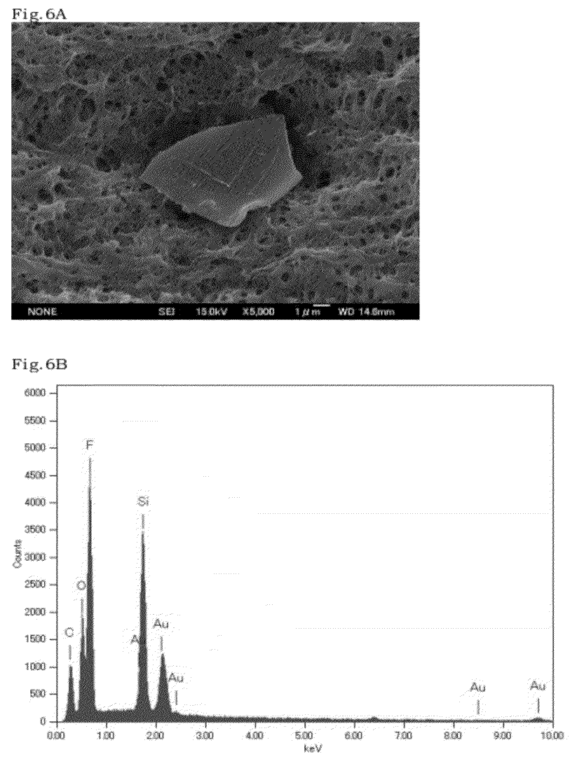

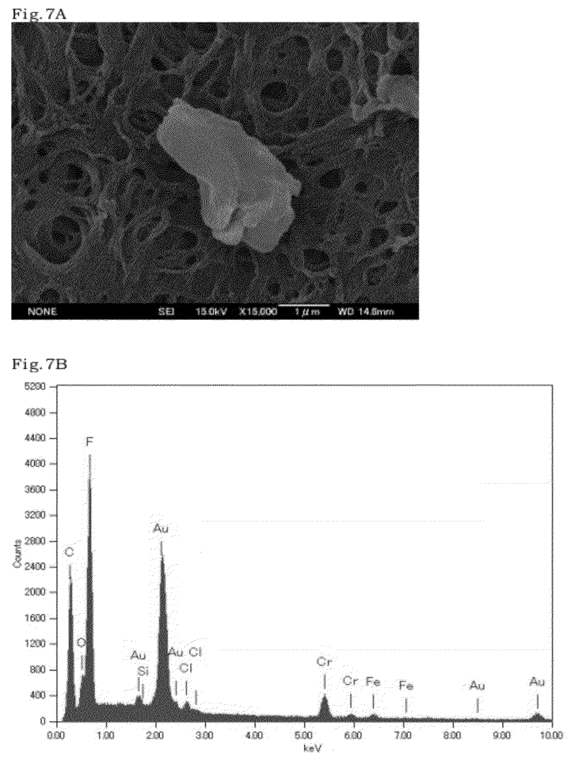

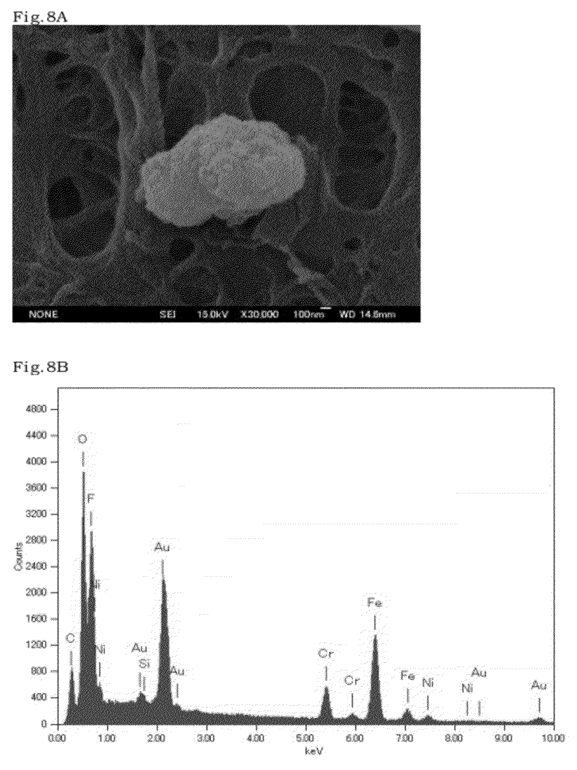

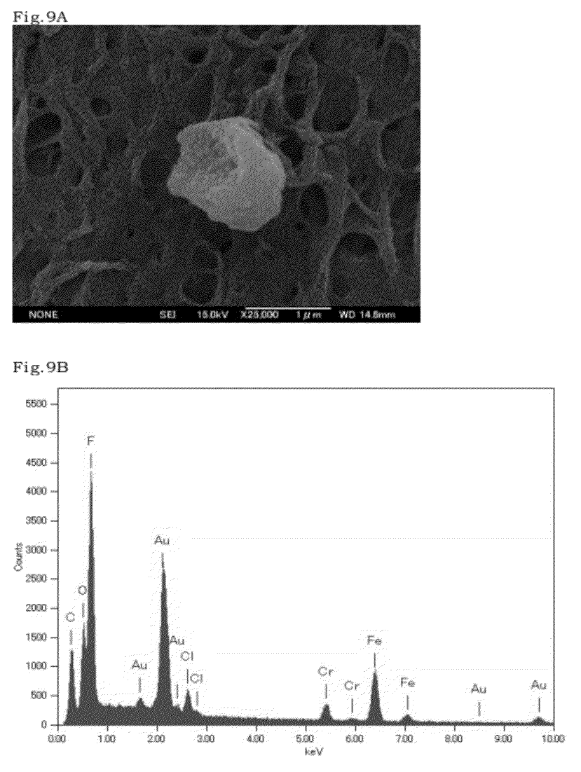

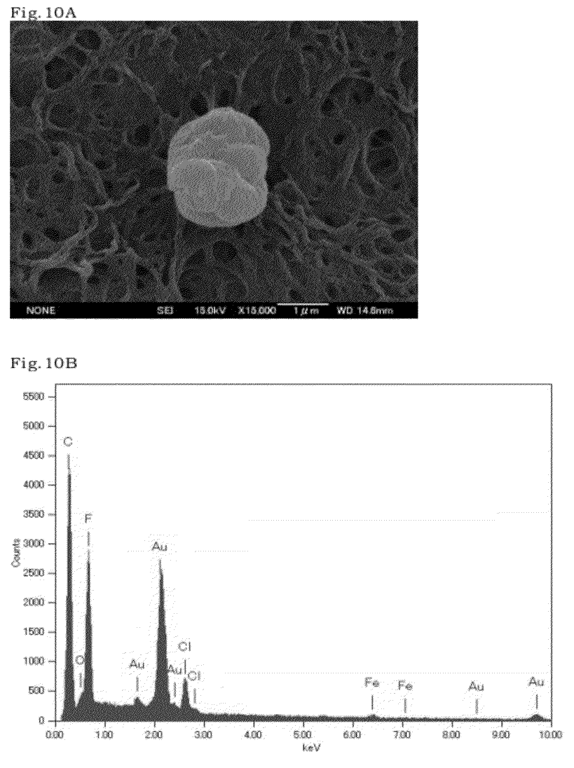

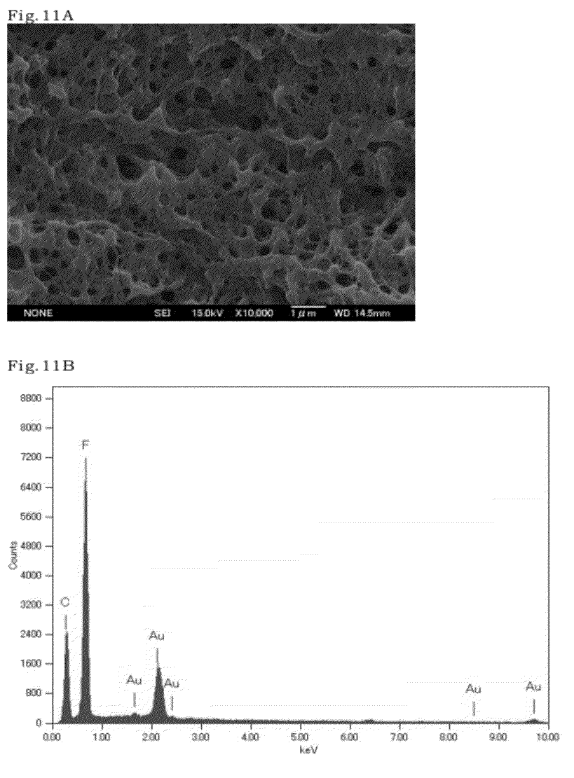

The analysis results (SEM pictures and element distribution charts) are shown in FIGS. 1 to 11.

### [Evaluation]

With regard to all of working examples 1 to 3, not more than 1500 number/gram of inclusions having a particle size of 0.5 μm to 20 μm, were contained, and the abnormal electrical discharges were not observed. Further, the presences of Fe, Cr, Ni, Si, Al, Co, C, Cl were recognized by the analysis of the particles. With regard to both comparative examples 1 and 2, over 1500 number/gram of inclusions having a particle size of 0.5 μm to 20 μm, were contained, and the abnormal electrical discharges were observed. Further, the presences of Fe, Cr, Ni were recognized more than eight times for working example 1 by the analysis of the particles.

What is claimed is:

1. An indium target containing not more than 1500 number/gram of inclusions having a particle size of 0.5 to 20 μm.

2. The indium target of claim 1, containing not more than 500 number/gram of inclusions having a particle size of 0.5 μm to 20 μm.

3. The indium target of claim 1 or 2, wherein the inclusion is one or more selected from metal, metal oxide, carbon, carbon compound and chloride compound.

4. The indium target of claim 3, wherein the inclusion is one or more metals selected from Fe, Cr, Ni, Si, Al and Co, or oxide of the metal.

5. A manufacturing method of an indium comprising melting raw indium in a container, supplying the melted indium to a mold through a plumbing, and then casting the indium by cooling in the mold,
wherein surface roughness (Ra) of parts in contact with the raw indium, of the container, the plumbing and the mold, is not more than 5 μm.
